(19) United States
(12) Patent Application Publication
(10) Pub. No.: US 2012/0031339 A1
(43) Pub. Date: Feb. 9, 2012

(54) DEPOSITION HEAD AND FILM FORMING APPARATUS

(75) Inventors: Yuji Ono, Miyagi (JP); Tomohiko Edura, Miyagi (JP); Teruyuki Hayashi, Miyagi (JP); Akitake Tamura, Yamanashi (JP); Misako Saito, Yamanashi (JP)

(73) Assignee: TOKYO ELECTRON LIMITED, Tokyo (JP)

(21) Appl. No.: 13/262,335

(22) PCT Filed: Apr. 2, 2010
(86) PCT No.: PCT/JP2010/056064

§ 371 Date: Oct. 26, 2011

(30) Foreign Application Priority Data
Apr. 3, 2009 (JP) 2009-090846
Jul. 13, 2009 (JP) 2009-164935
Feb. 26, 2010 (JP) 2010-041352

(51) Int. Cl. C23C 16/455

(52) U.S. Cl. 118/724

(57) ABSTRACT

There is provided a deposition head capable of discharging a material gas having a uniform flow rate and equi-thermal property from each component in a large-sized substrate as well as a conventional small-sized one for forming a uniform thin film. A deposition apparatus including the deposition head is also provided. The deposition head is provided within a deposition apparatus for forming a thin film on a substrate and configured to discharge a material gas toward the substrate. The deposition head includes an outer casing, and an inner casing provided within the outer casing and into which the material gas is introduced. In the inner casing, an opening configured to discharge the material gas toward the substrate is formed, and a heater configured to heat the material gas is provided at an outer surface of the outer casing or in a space between the outer casing and the inner casing.

### TECHNICAL FIELD

The present disclosure relates to a deposition head for depositing an organic film, for example, in manufacturing an organic EL device, and relates to a deposition apparatus including the deposition head.

### BACKGROUND ART

Recently, an organic EL device utilizing electroluminescence (EL) has been developed. Since the organic EL device consumes lower power compared with a cathode-ray tube or the like and is self-luminescent, there are some advantages such as a view angle wider than that of a liquid crystal display (LCD).

The most basic structure of this organic EL device includes an anode (positive electrode) layer, a light-emitting layer, and a cathode (negative electrode) layer stacked sequentially on a glass substrate to form a sandwiched shape. In order to transmit light from the light-emitting layer, a transparent electrode made of ITO (Indium Tin Oxide) is used for the anode layer on the glass substrate. Such organic EL device is generally manufactured by forming the light-emitting layer and the cathode layer in sequence on the glass substrate having thereon the ITO layer (anode layer) and by additionally forming a sealing film.

The organic EL device as described above is generally manufactured by a processing system including various film forming apparatuses or etching apparatuses configured to form a light emitting layer, a cathode layer, a sealing layer, and the like.

By way of example, as a general method of forming a light emitting layer, there has been known a method in which a material gas is supplied to a deposition head from a material gas supply source and the material gas is discharged from the deposition head toward a glass substrate so as to be deposited thereon.

Patent Document 1 describes a deposition head 20 including a single dispersion plate 41 having multiple through-holes 40 as depicted in FIG. 2, and a deposition head 20 including multiple branch flow lines 44 branched from a gas flow line communicating with a material gas inlet port 43 as depicted in FIG. 3.
Patent Document 1: Japanese Patent Laid-open Publication No. 2004-079904

### DISCLOSURE OF THE INVENTION

### Problems to be Solved by the Invention

However, if an organic film is formed by using a deposition head including a dispersion plate depicted in FIG. 2, the amount of the material gas passing through through-holes of the dispersion plate may vary depending on a distance from a supply port through which the material gas is supplied into the deposition head. Further, since an equi-thermal property of the material gas is not considered, there is a problem that a temperature of the material gas is not uniformized and a film is not formed on a substrate in a sufficiently uniform manner.

A deposition head including branch flow lines therein as depicted in FIG. 3 is used for a small-sized target substrate corresponding to a small-sized display of about 20 inches. If a film is formed on a large-sized glass substrate used for a large-sized display, of which production has recently been demanded, having a size, for example, about 4.6 times than a conventional one, a deposition head needs to become larger accordingly. When branch flow lines are formed within a large-sized deposition head, the number of the branch flow lines may be increased. Thus, it takes a long time to manufacture the deposition head and manufacturing costs may be increased. Further, if the number of the branch flow lines is increased, a temperature distribution of a material gas passing through the branch flow lines may not become uniformized. Thus, a material gas cooled down to a low temperature can be solidified within the branch flow lines.

Accordingly, the present disclosure provides a deposition head capable of discharging a material gas having a uniform flow rate and equi-thermal property from each component in a large-sized substrate as well as a conventional small-sized one and capable of forming a uniform thin film and also provides a deposition apparatus including the deposition head.

### Means for Solving the Problems

In accordance with an aspect of the present disclosure, there is provided a deposition head provided within a deposition apparatus for forming a thin film on a substrate and configured to discharge a material gas toward the substrate. The deposition head may include an outer casing, and an inner casing provided within the outer casing and into which the material gas is introduced. In the inner casing, an opening configured to discharge the material gas toward the substrate may be formed, and a heater configured to heat the material gas may be provided at an outer surface of the outer casing or in a space between the outer casing and the inner casing.

Further, the heater may be fixed to a plate member provided between the outer casing and the inner casing, and the heater may be provided along a periphery of a side surface of the outer casing or the inner casing. The heater may include a sheath heater or a cartridge heater, and a spacer member configured to bring an inner surface of the outer casing into partial contact with an outer surface of the inner casing may be provided on at least one of the outer casing and the inner casing. Moreover, a sealed space may be formed between the outer casing and the inner casing. The heater may be provided within the sealed space, and a volatile liquid may be provided in the sealed space.

Further, thermal conductivity of the outer casing may be equal to or higher than thermal conductivity of the inner casing. In this deposition head, since the thermal conductivity of the outer casing is high, heat from the heater is rapidly transferred throughout the whole outer casing, and the whole outer casing is uniformly heated. Further, heat is transferred from the outer casing to the inner casing via a spacer member that brings the inner surface of the outer casing into partial contact with the outer surface of the inner casing. As a result, the inner casing is heated. In this case, the spacer member that brings the inner surface of the outer casing into contact with the outer surface of the inner casing may be provided over the whole outer casing or the whole inner casing. Therefore, the heat may be transferred substantially uniformly to the whole inner casing, and the whole inner casing may be uniformly heated. Thus, the material gas introduced into the inner casing may be heated under the substantially same conditions and the material gas may have a uniform temperature within the inner casing. Thus, the material gas with the uniform temperature distribution may be discharged through the opening toward the substrate and a uniform film may be formed.

The spacer member may be provided on either or both of the outer casing and the inner casing, and a spacer member provided on the outer casing may be made of a material different from a material of a spacer member provided on the inner casing. The spacer member may include multiple protrusions formed by press molding or a filling material.

The press molding may include an emboss processing or a welding processing. A material of the outer casing may include stainless steel or copper. A material of the inner casing may include stainless steel. A thickness of at least a part of the inner casing may be about 3 mm or less. A gas dispersion plate may be provided within the inner casing. The gas dispersion plate may include a mesh-shaped baffle plate or a punching metal plate.

A thermal conductive film may be formed on either or both of the inner casing and the outer casing. The thermal conductive film may be formed on at least an outer surface of the inner casing. A discharge plate configured to uniformly discharge the material gas may be provided in the opening. The discharge plate may include a slit configured to discharge the material gas or the discharge plate may include multiple discharge holes configured to discharge the material gas. The discharge plate may be formed of a stainless steel plate, a stainless block, a cooper plate, or a copper block.

In accordance with another aspect of the present disclosure, there is provided a deposition apparatus for forming an organic thin film on a substrate. The deposition apparatus may include a processing chamber configured to accommodate therein a substrate; and a deposition head including an opening configured to discharge a material gas toward the substrate within the processing chamber. The deposition head may include a carrier gas supply unit configured to supply a carrier gas that transports the material gas. An inside of the processing chamber may be depressurized.

### Effect of the Invention

In accordance with the present disclosure, there is provided a deposition head capable of discharging a material gas at a uniform flow rate and temperature from each component toward a large-sized substrate as well as a conventional small-sized one while securing equi-thermal property and capable of forming a uniform thin film, and a deposition apparatus including the deposition head.

### BRIEF DESCRIPTION OF THE DRAWINGS

FIG. 1 is a schematic view of a film forming apparatus 1 performing deposition.

FIG. 2 is an explanatory diagram of a deposition head that includes a single dispersion plate 41 having multiple through-holes 40.

FIG. 3 is an explanatory diagram of a deposition head 20 that includes multiple branch flow lines 44 branched from a gas flow line communicating with a material gas inlet port 43.

FIGS. 4A to 4D are explanatory diagrams of a manufacturing process of an organic EL device (A).

FIG. 5 is a schematic explanatory diagram of a deposition apparatus 60.

FIG. 6A is a perspective view of a deposition head 66 when viewed from a diagonally lower side, and FIG. 6B is a bottom view of the deposition head 66.

FIG. 7 is a perspective view of an outer casing 70.

FIG. 8 is a perspective view of an inner casing 71.

FIGS. 9A and 9B are explanatory diagrams showing that a heater 77 is provided.

FIG. 10 is a schematic cross-sectional view of a deposition head 66a in which a heater 77 is provided in accordance with another embodiment of the present disclosure.

FIGS. 11A and 11B are side views of a deposition head 66 to show a shape of a heater 77 provided therein.

FIG. 12 is a schematic cross-sectional view of a deposition head 66b in which a heater 77 is provided in accordance with a second another embodiment of the present disclosure.

FIG. 13A is a schematic view of a deposition head 66 including a discharge plate 95a having a slit 96. FIG. 13B is a schematic view of the deposition head 66 including the discharge plate 95a having discharge holes 97.

FIG. 14A is a schematic front view of a deposition head 66 having a sealed space. FIG. 14B is a schematic side view of the deposition head 66 having the sealed space.

FIGS. 15A and 15B show a result of an experimental example.

FIGS. 16A to 16C are graphs showing a result of an experimental example 2.

### EXPLANATION OF CODES

1: Film forming apparatus
10: Chamber
11: Substrate holding room
12, 54: Holding tables
13: Vacuum pump
14: Exhaust port
20, 66, 66a, 66b: Deposition heads
30: Material supply unit
40: Through-holes
41: Dispersion plate
43: Material gas inlet port
44: Branch flow line
50: Anode layer
51: Light emitting layer
52: Cathode layer
53: Sealing film layer
60: Deposition apparatus
61: Processing chamber
62: Gate valve
63: Exhaust line
65: Rail
67: Material supply source
68: Material supply line
70: Outer casing (first casing)
71: Inner casing (second casing)
72, 73: Opening surfaces
77, 78: Heaters
80: Groove
81: Heater bloc
82: Material gas inlet port
83: Baffle plate
85: Protrusion
90: Plate member
95: Discharge plate
96: Slit
97: Discharge holes
100: Sealed space
G: Substrate
L: Liquid

### BEST MODE FOR CARRYING OUT THE INVENTION

Hereinafter, embodiments of the present disclosure will be described in detail with reference to the accompanying drawings. In the specification and the drawings, elements having substantially the same function are assigned same reference numerals and redundant description thereof may be omitted.

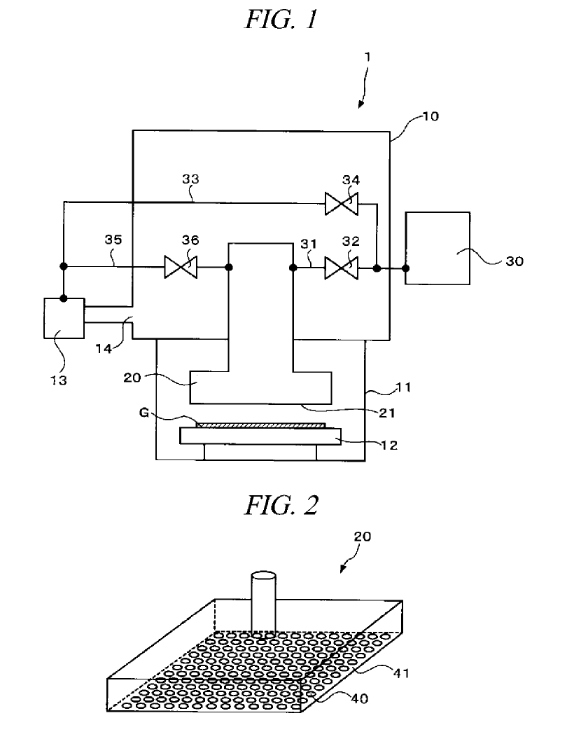

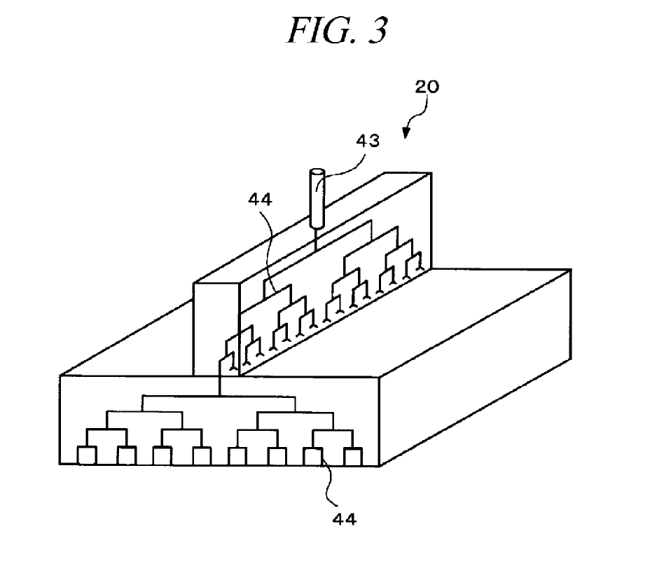

FIG. 1 is a schematic view of a film forming apparatus 1 performing deposition. As depicted in FIG. 1, the film forming apparatus 1 may include a chamber 10, a substrate holding chamber 11 provided under the chamber 10, and a deposition head 20 extended over the chamber 10 and the substrate holding chamber 11. The deposition head 20 may be positioned such that its opening 21 configured to discharge a material gas within the substrate holding chamber 11 faces downwards. Further, a holding table 12 configured to horizontally hold a substrate G may be provided within the substrate holding chamber 11, and the substrate G is mounted on the holding table 12 such that the substrate G's upper surface on which a film is formed faces upwards (face-up state). Thus, the opening 21 of the deposition head 20 may be positioned so as to face the upper surface of the substrate G.

The chamber 10 may include an exhaust port 14 through which exhaustion is performed by a vacuum pump 13. During a film formation, the insides of the chamber 10 and the substrate holding chamber 11 may be in a vacuum state. The deposition head 20 may communicate, via a material supply line 31, with a material supply unit 30 provided outside the chamber 10. Further, a valve 32 configured to control a supply of a material gas may be provided in the material gas supply line 31. The material supply line 31 may be connected to a gas retreat line 33 communicating with the vacuum pump 13 and retreating a gas when the valve 32 is closed. Further, a valve 34 may be provided in the gas retreat line 33. The deposition head 20 may be connected to a gas outlet line 35 communicating with the vacuum pump 13 and collecting a remaining material gas within the deposition head 20 after the film formation. Further, a valve 36 may be provided in the gas outlet line 35.

In the deposition head 20 provided within the film forming apparatus 1 configured as described above, in order to form a uniform thin film on the substrate G, it may be required to discharge the material gas supplied from the material supply unit 30 toward the substrate G through the opening 21 at a flow rate as uniform as possible and with a secured equi-thermal property.

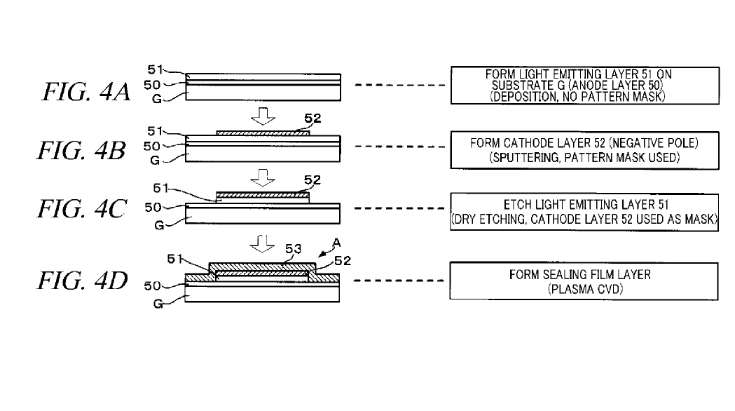

FIGS. 4A to 4D are explanatory diagrams of a manufacturing process of an organic EL device (A) manufactured by various film forming apparatuses including a deposition apparatus 60 using a deposition head 66 in accordance with an embodiment of the present embodiment. As depicted in FIG. 4Aa, the substrate G on which an anode (positive) layer 50 is formed may be provided. The substrate G may be made of a transparent material such as glass. The anode layer 50 may be made of a transparent conductive material such as ITO (Indium Tin Oxide). Further, the anode layer 50 may be formed on an upper surface of the substrate G by means of, for example, sputtering.

Above all, as depicted in FIG. 4A, a light emitting layer (organic layer) 51 may be formed on the anode layer 50 by means of deposition. The light emitting layer 51 may be configured as a multi-layered structure in which, for example, a hole transport layer, a non-light-emitting layer (electron blocking layer), a blue light emitting layer, a red light emitting layer, a green light emitting layer, and an electron transport layer are layered.

Then, as depicted in FIG. 4B, a cathode (negative) layer 52 made of, for example, Ag and Al may be formed on the light emitting layer 51 by means of, for example, sputtering using a mask.

Subsequently, as depicted in FIG. 4C, for example, the light emitting layer 51 may be dry-etched by using the cathode layer 52 as a mask, so that the light emitting layer 51 may be patterned.

Thereafter, as depicted in FIG. 4D, a sealing film layer 53 made of an insulating material such as silicon nitride (SiN) may be formed so as to cover the light emitting layer 51, the cathode layer 52, and an exposed region of the anode layer 50. The sealing film layer 53 may be formed by means of, for example, microwave plasma CVD.

In the organic EL device A manufactured as described above, the light emitting layer 51 may emit light by applying a voltage between the anode layer 50 and the cathode layer 52. This organic EL device A can be used for a display device or a surface light emitting device (illumination/light source) and can be used for other electronic devices.

Then, the deposition apparatus 60 for forming the light emitting layer 51 depicted in FIG. 4A will be explained with reference to the drawings. Further, since film forming processes such as sputtering, etching and plasma CVD other than the film forming process depicted in FIG. 4A may be performed by typical apparatuses and methods, detailed explanation thereof will be omitted.

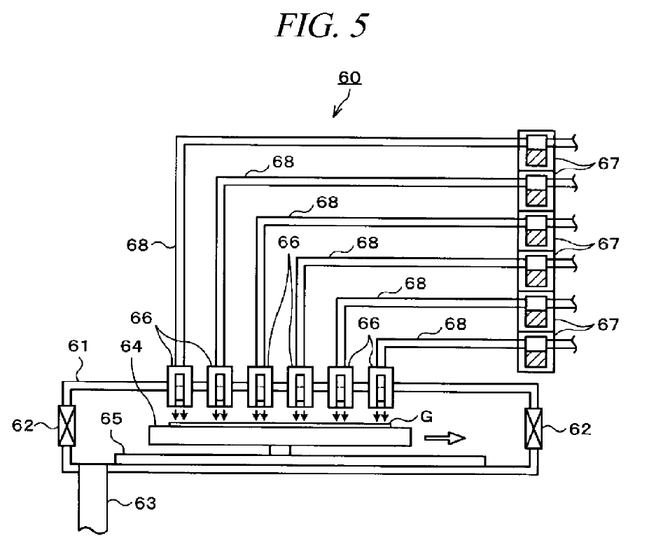

FIG. 5 is a schematic explanatory diagram of a deposition apparatus 60 in accordance with an embodiment of the present disclosure. The deposition apparatus 60 depicted in FIG. 5 may form an organic film including the light emitting layer 51 depicted in FIG. 4A by means of deposition.

The deposition apparatus 60 may include a sealed processing chamber 61. The sealed processing chamber 61 may have a rectangular shape of which a longitudinal direction corresponds to a transfer direction of the substrate G. Front and rear surfaces of the processing chamber 61 may be connected to another film forming apparatus or the like via gate valves 62.

A bottom surface of the processing chamber 61 may be connected to an exhaust line 63 including a vacuum pump (not illustrated), so that the inside of the processing chamber 61 may be depressurized. Further, the processing chamber 61 may include therein a holding table 64 configured to horizontally hold the substrate G. The substrate G may be mounted on the holding table 64 in a face-up state in which the substrate G's upper surface on which the anode layer 50 is formed faces upwards. The holding table 64 may be configured to move on a rail 65 provided along the transfer direction of the substrate G so as to transfer the substrate G.

On a ceiling surface of the processing chamber 61, multiple deposition heads 66 (for example, six in FIG. 5) may be provided along the transfer direction of the substrate G. Each of the deposition heads 66 may be connected, via each of material supply lines 68, to each of multiple material supply sources 67, respectively. Each of the material supply lines 68 may be configured to supply vapor (material gas) of a film forming material for forming the light emitting layer 51. While the vapor of the film forming material supplied from the material supply sources 67 are discharged through each of the deposition heads 66, the substrate G held on the holding table 64 may be transferred. Thus, a hole transport layer, a non-light-emitting layer, a blue light emitting layer, a red light emitting layer, a green light emitting layer, and an electron transport layer may be stacked in sequence on the upper surface of the substrate G, and the light emitting layer 51 may be formed on the upper surface of the substrate G.

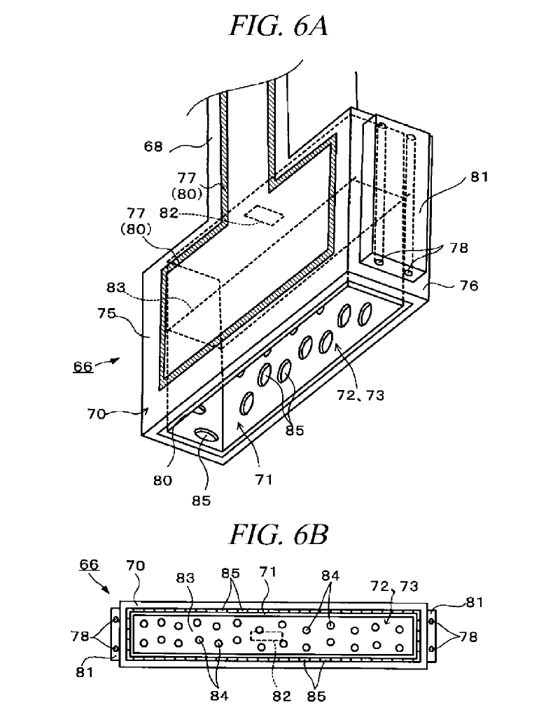

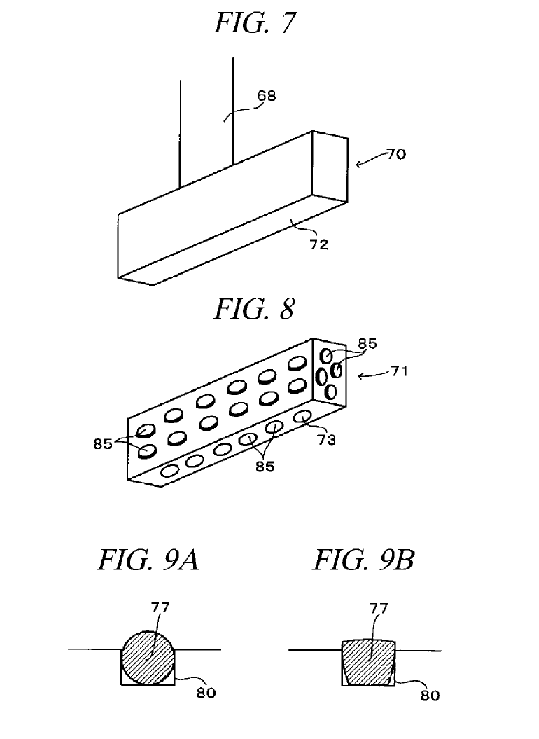

FIGS. 6A and 6B are schematic explanatory diagrams of the deposition head 66. FIG. 6A is a perspective view of the deposition head 66 when viewed from a diagonally lower side, and FIG. 6B is a bottom view of the deposition head 66. FIG. 7 is a perspective view of an outer casing 70, and FIG. 8 is a perspective view of an inner casing 71. Although the multiple deposition heads 66 are depicted in FIG. 5, each deposition head 66 may have the same configuration. Further, as described above in detail, within the processing chamber 61, a lower surface of the deposition head 66 may face the upper surface of the substrate G horizontally held on the holding table 64 in the face-up state. Hereinafter, in the present specification, the outer casing 70 will be referred to as a first casing 70 and the inner casing 71 will be referred to as a second casing 71.

The first casing 70 and the second casing 71 may have a rectangular shape. The first casing 70 may be slightly larger than the second casing 71. Further, the deposition head 66 may be configured to include the first casing 70 inserting the second casing 71 therein. Openings 72 and 73 may be formed on a lower surface of the first casing 70 and a lower surface of the second casing 71, respectively. The second casing 71 may be inserted into the lower opening 72 of the first casing 70, so that both openings 72 and 73 may be overlapped with each other.

The first casing 70 may be made of a material having higher thermal conductivity than the second casing 71. For example, copper may used for the first casing 70. An upper surface (a surface facing the opening 72) of the first casing 70 may be connected to the material supply line 68 communicating with the material supply source 67 depicted in FIG. 5.

Between side surfaces 75 and 76 of the first casing 70, the side surface 75 is larger than the side surface 76. The side surface 75 may include a groove 80 in which a heater 77 is embedded. The heater 77 may be provided along a periphery of the square-shaped side surface 75. Since the heater 77 is embedded in the groove 80, a contact surface between the side surface 75 of the first casing 70 and the heater 77 may increase, resulting in an increase of thermal conductivity.

In the drawing, the groove 80 may extend to a side surface of the material supply line 68 connected to the upper surface of the first casing 70, and the heater 77 may be embedded therein.

In order to embed the heater 77 in the groove 80, as depicted in FIG. 9A, the heater 77 may be just put in the groove 80. Further, as depicted in FIG. 9B, the heater 77 may be put in the groove 80, and then, be pressed down from an upper direction of the groove 80. As a result, the side surface 75 of the first casing 70 can be securely in contact with the heater 77 and a contact surface therebetween may increase, resulting in increasing thermal conductivity.

Between the side surfaces 75 and 76 of the first casing 70, the side surface 76 is smaller than the side surface 75. The side surface 76 may have thereon a heater block 81 including therein a heater 78. The heater block 81 may be made of a material having high thermal conductivity such as copper. A surface of the heater block 81 may be contacted with the side surface 76 of the first casing 70. Thus, heat transferred from the heater 78 to the heater block 81 may be rapidly transferred to the entire side surface 76 of the first casing 70.

The inner casing 71 may be made of a material having less thermal conductivity than the first casing 70. For example, stainless steel may be used for the inner casing 71. In an upper surface (a surface facing the opening 73) of the inner casing 71, a material gas inlet port 82 through which a material gas is introduced from the material supply line 68 may be formed.

As depicted in FIGS. 6A and 6B, within the second casing 71, a baffle plate 83 serving as a gas dispersion plate may be provided so as to partition the opening 73 from the material gas inlet port 82. The baffle plate 83 may be spaced away from the opening 73 and arranged so as to be in parallel with the opening 73 within the second casing 71. The baffle plate 83 may have, for example, a mesh shape, and multiple holes 84 may be formed in the entire surface of the baffle plate 83. The baffle plate 83 provided within the second casing 71 may be one or more, and may be provided at a certain position within the second casing 71. The number and the arrangement of the baffle plate 83 may be appropriately changed depending on a flow velocity or a flow rate of a material gas in order that the material gas can be diffused uniformly within the second casing 71. The baffle plate 83 may have a shape suitable for diffusing the material gas and may have, for example, a punching metal shape other than the mesh shape.

As depicted in FIG. 8, multiple protrusions 85 serving as spacer members may be formed over the second casing 71. These multiple protrusions 85 may be formed by means of press molding such as an emboss processing, and a height of each protrusion 85 may be substantially uniform. The multiple protrusions 85 may be provided uniformly in the entire outer surfaces of the second casing 71. As described above, since the second casing 71 is inserted into the first casing 70, the inner surfaces of the first casing 70 and the outer surfaces of the second casing 71 may be in partial contact with each other at positions of the multiple protrusions 85. Further, in the deposition head 66 in accordance with the present embodiment, as depicted in FIG. 8, the protrusions 85 serving as the spacer members may be formed in the second casing 71. However, if it is verified that thermal conduction from the first casing 70 to the second casing 71 is rapidly performed without providing the spacer members (protrusions 85), the spacer members (protrusions 85) need not be provided in the second casing 71.

Within the processing chamber 61 of the deposition apparatus 60 including the deposition head 66 depicted in FIG. 5 as described above, the substrate G having the anode layer formed on its upper surface, i.e., in the face-up state may be mounted on the holding table 64 as depicted in FIG. 5, and may be transferred along the rail 65. A vapor of a film forming material (material gas) may be introduced into the second casing 71 from the material supply source 67 through the material supply line 68. Then, the material gas introduced into the second casing 71 through the material gas inlet port 82 depicted in FIG. 6 may be diffused while passing through the baffle plate 83. Then, the material gas may be uniformly discharged from the lower surfaces (opening and 73) of the deposition head 66 toward the upper surface of the substrate G.

In the deposition head 66 depicted in FIGS. 6A and 6B, the first casing 70 may be heated by the heaters 77 and 78 such as a sheath heater or a cartridge heater. In this case, since the first casing 70 may be made of a material having high thermal conductivity, heat may be rapidly transferred from the heaters 77 and 78 to the entire of the first casing 70. Thus, the entire of the first casing 70 may be heated uniformly. Via the multiple protrusions 85 that bring the inner surfaces of the first casing 70 in partial contact with the outer surfaces of the second casing 71, heat may be transferred from the first casing 70 to the second casing 71, so that the second casing 71 may be heated. In this case, since the multiple protrusions 85 that bring the inner surfaces of the first casing 70 in contact with the outer surfaces of the second casing 71 may be provided in the whole second casing 71, heat may be transferred substantially uniformly to the entire of the second casing 71. Thus, the second casing 71 may be heated uniformly. Accordingly, the material gas introduced into the second casing 71 may be heated within the second casing 71 under the same conditions, and a temperature of the material gas within the second casing 71 may be uniformized. Thus, the material gas having the uniform temperature may be discharged from the lower surface (openings 72 and 73) of the deposition head 66 toward the upper surface of the substrate G as depicted in FIG. 5.

That is, in the deposition head 66 in accordance with the present embodiment, as depicted in FIGS. 4A to 4D, the gas may be uniformly (equi-thermally) discharged toward the substrate G in consideration of both the flow rate and the temperature of the gas. As a result, an organic thin film (light emitting layer 51) having high uniformity may be formed on the substrate G. Further, as compared with the conventional deposition head including therein branch flow lines, in accordance with the deposition head 66 of the present embodiment, an equi-thermal property can be secured, and solidification of the material gas at a low temperature region can be prevented.

If the material gas is discharged to a large-sized substrate used for a large-sized display, which is recently in high demand, a metal plate structure formed by cutting steel may be provided. In this case, as compared with the conventional deposition head including therein branch flow lines, it may be possible to greatly reduce manufacturing costs for the deposition head 66 in accordance with the present embodiment. Conventionally, a sheet-shaped heater (mica heater) of high cost has been used for a deposition head that discharges a material gas onto a small-sized substrate for a small-sized display. However, if the sheet-shaped heater is used for a large-sized deposition head for a large-sized substrate costs may be increased due to the large size. Therefore, by using pipe-shaped heaters 77 and such as the sheath heater or the cartridge heater described in the present embodiment together with the sheet-shaped heater, it may be possible to reduce cost, and also possible to secure an equi-thermal property within the deposition head.

There has been described the embodiment of the present disclosure, but the present disclosure is not limited to the above-described embodiment. It would be understood by those skilled in the art that various changes and modifications may be made within the scope of the accompanying claims and it shall be understood that all changes and modifications are included in the scope of the present disclosure.

By way of example, in the above-described embodiment, the deposition apparatus 60 for manufacturing the organic EL device A has been explained. Further, the present disclosure can be also applied to a case where a film is formed by means of deposition such as Li deposition in processes of various electronic devices. Although it has been described that the substrate G as a target object is a glass substrate, the glass substrate may include a silicon substrate, a square substrate, a circular substrate or the like. Further, the present disclosure can be applied to a target object other than a substrate.

In the present embodiment, it has been described that the heaters 77 (groove 80) and 78 (heater block 81) are provided in both side surfaces 75 and 76 of the deposition head 66. However, the present disclosure is not limited thereto, and the heaters 77 and 78 may be provided in only one of the side surfaces 75 and 76. That is, one of the heaters 77 and 78 provided in the side surfaces 75 and 76 may be omitted. Desirably, a shape, the number, and an arrangement of the heaters 77 and 78 may be changed appropriately depending on a deposition head 66's temperature measured while being heated. The arrangement thereof is not limited to an example shown in FIG. 6.

By way of example, FIG. 10 is a schematic cross-sectional view of a deposition head 66a having a heater 77 in a different manner in accordance with another embodiment of the present disclosure. As depicted in FIG. 10, in the deposition head 66a, the heater 77 may be provided in a space between the first casing 70 and the second casing 71 with a plate member 90 therebetween. The first casing 70 and the second casing 71 may not be directly contacted with each other. Desirably, the heater 77 may not be fixed to the second casing 71. Further, the heater 77 may be partially fixed to the first casing 70 such that heat leakage may become reduced. Further, the heater 77 may be fixed to another member replacing the above-described plate member 90, and may be provided between the second casing 71 and the first casing 70. Thus, an equi-thermal property within the deposition head 66 can be secured with more efficiency. FIG. 10 shows that lower ends (peripheries of openings 72 and 73 in FIG. 10) of the first casing 70 and the second casing 71 are not in contact with each other. However, the present disclosure is not limited thereto, and the first casing 70 and the second casing 71 may be in contact with each other at the peripheries of the openings 72 and 73. Further, the heater 77 (plate member 90) may be provided airtightly between the first casing 70 and the second casing 71.

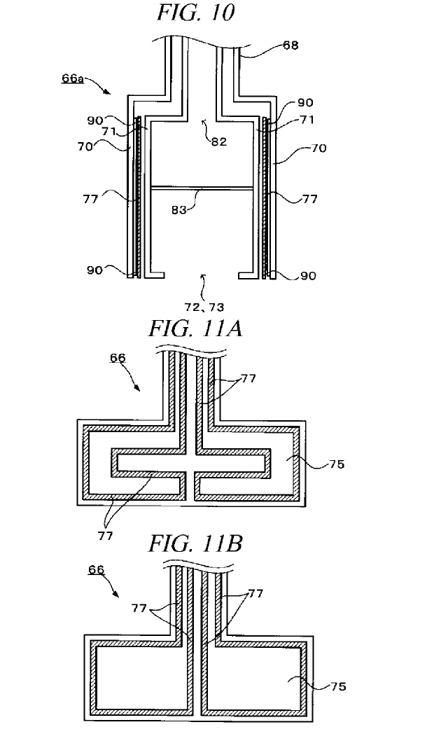

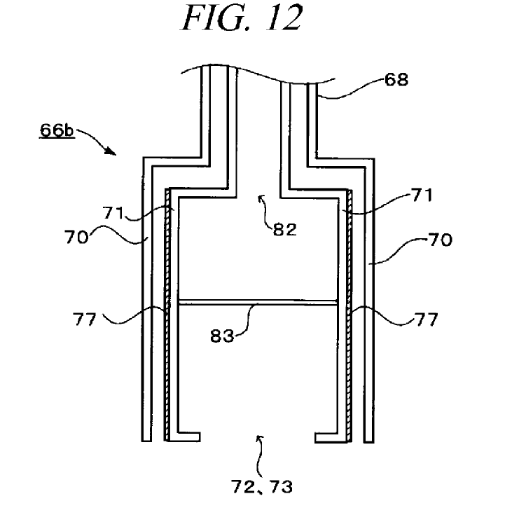

In the deposition head 66 in accordance with the above-described embodiment, as depicted in FIGS. 6A and 6B, the groove 80 may have a circular ring shape in the side surface 75, and the heater 77 may be put in the groove 80. However, a shape of the heater 77 is not limited to the circular ring shape. FIGS. 11A and 11B are side views of a deposition head 66 to show a shape of a heater 77 provided therein. A shape of the heater 77 can be changed appropriately. As depicted in FIG. 11A, the heater 77 can be provided on the side surface 75 in a shape of heating both an outer periphery portion and a central portion of the side surface 75. By providing the heater 77 in the central portion in addition to the periphery portion of the side surface 75 as shown in FIG. 11A, a temperature at an outer periphery portion and a central portion of the deposition head 66 can be substantially uniformized and a temperature difference on a cross section within the deposition head 66 can be decreased. Therefore, an equi-thermal property of a material gas within the deposition head 66 can be secured with high accuracy.

If an equi-thermal property is sufficiently secured in the side surface 75, even if arrangement density of the heater 77 is reduced, the equi-thermal property within the deposition head 66 can be sufficiently secured. Therefore, as depicted in FIG. 11B, the arrangement density of the heater 77 can be reduced as compared with the example depicted in FIG. 11A. The arrangement density of the heater 77 can be changed appropriately depending on a temperature difference on the cross section within the deposition head 66. Since the inside of the deposition head 66 is in a vacuum state, heat transfer may hardly occur in its central portion as compared with its outer periphery portion. Therefore, it may be desirable to arrange a heater based on a heat transfer condition such that the outer periphery portion, rather than the central portion, can be further heated and thermally uniformized by the heater 77.

The arrangement shape of the heater 77 depicted in FIG. 11 may not limited to the example where the heater 77 is provided in the side surface 75 of the deposition head 66, i.e. the outer surface of the outer casing 70. By way of example, it can be applied to the heater 77 provided in the deposition head 66a in accordance with another embodiment of the present disclosure as depicted in FIG. 10.

In the deposition head 66 in accordance with the above-described embodiment, the first casing 70 may be made of copper; the second casing 71 may be made of stainless steel; and the heater 77 may be provided in the outer surface of the first casing 70. However, the present disclosure is not limited thereto. The heater 77 does not need to be provided in the outer surface of the first casing 70 in order to secure the equi-thermal property within the deposition head 66. Therefore, hereinafter, there will be explained, as a second another embodiment of the present disclosure, an example where an arrangement of the heater 77 and a material of each casing are different from the above-described embodiment.

By way of example, in the second another embodiment of the present disclosure, the first casing 70 and the second casing 71 may be made of stainless steel, and only the second casing 71 may be coated with a thermal conductive film such as a copper coating having a thickness of about 30 microns or more. In this case, desirably, the heater 77 may be provided between the first casing 70 and the second casing 71 differently from the above-described embodiment. Further, in addition to the second casing 71, if required, the first casing 70 may be coated appropriately with the thermal conductive film in order to reduce non-uniformity in temperatures on a cross section within a deposition head 66. That is, whether either or both of the first casing 70 and the second casing 71 is coated with the thermal conductive film may be determined appropriately depending on temperature differences on the cross section within the deposition head 66. Further, it may be allowed to coat only one side of each casing with the thermal conductive film. However, typically, in case of a copper coating, for example, since a stainless steel plate is immersed in a copper coating tank, the copper coating may be generally performed on both sides of the stainless steel plate.

FIG. 12 is a schematic cross-sectional view of a deposition head 66b in which only the second casing 71 is coated with the thermal conductive film such as the cooper coating. FIG. 12 does not show the thermal conductive film. In the deposition head 66b depicted in FIG. 12, the outer surface of the second casing 71 may be coated with the thermal conductive film. Further, the heater 77 may be provided on the outer surface of the second casing 71 in a space between the first casing 70 and the second casing 71, which are not in contact with each other. Since the outer surface of the second casing 71 is coated with the thermal conductive film, even if the heater 77 is not provided in the entire outer surface of the second casing 71, the deposition head 66b can be sufficiently heated and thermally uniformized. For this reason, in view of costs, the heater 77 provided on the outer surface of the second casing 71 can be arranged in a low density as depicted in FIG. 11B.

As described above, since each casing (particularly, the second casing 71) made of stainless steel is coated with a thermal conductive film such as a copper coating, it may be possible to secure hardness of the casing against thermal deformation. Further, thermal conductivity may be increased, and, thus, it may be possible to suppress non-uniformity in temperature in each component within the deposition head 66. Since thermal conductivity of each casing (particularly, the second casing 71) is increased, the number of the heaters 77 can be reduced as depicted in FIG. 11B. Thus, the deposition head 66 may be cost effective. In this case, whether either or both of the first casing 70 and the second casing 71 is coated with a copper coating may be determined appropriately depending on a temperature distribution measured in the deposition head 66.

That is, since the first casing 70 and the second casing 71 are made of stainless steel, costs can be greatly reduced, and hardness can be increased as compared with a case where a casing is made of copper. Further, since the stainless steel may be coated with the thermal conductive film, an equi-thermal property within the deposition head 66 can be secured. Further, it may be possible to avoid deformation caused by the copper heat, which may be generated in a case where a casing is made of a copper plate having high thermal conductivity. Herein, the copper coating has been described as the thermal conductive film for increasing thermal conductivity of the stainless steel. However, the thermal conductive film may not be limited to the copper coating. Instead, a film having a higher thermal conductivity than a basic material (material of a casing) can be employed. By way of example, it may be possible to conduct a coating capable of increasing thermal conductivity such as a gold coating and a silver coating. Further, a thermal conductive film may be formed by a junction process of the foil such as a gold/silver foil, or a blast process or a diffusion junction process. However, it may be desirable to conduct a copper coating in view of costs.

In the deposition head 66 in accordance with the above-described embodiment, the opening 72 (73) may be formed by opening one of the side surfaces of the rectangular casing. The material gas within the deposition head 66 may be dispersed by the gas dispersion plate (baffle plate 83) provided in the deposition head 66 and discharged to the substrate G through the opening 72 (73). However, the material gas within the deposition head 66 cannot be dispersed sufficiently by only the gas dispersion plate. Therefore, the material gas may not be discharged uniformly to the substrate G through the opening 72 (73), and a film may not be formed uniformly. In this case, desirably, an discharge plate formed of, for example, a copper plate and configured to allow the material gas to be discharged uniformly through the opening 72 (73) may be provide in the deposition head 66 described in the above-described embodiment.

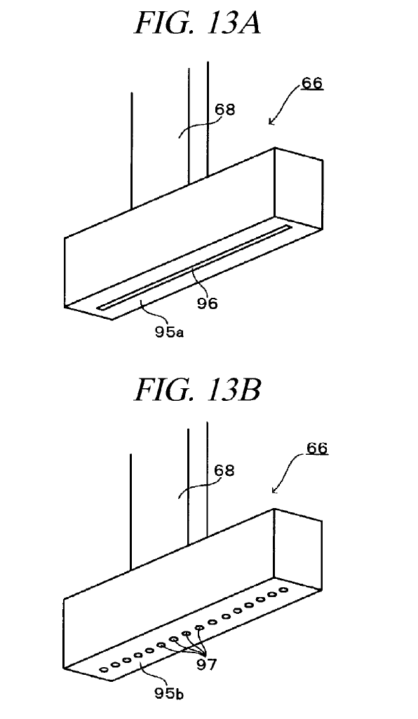

FIGS. 13A and 13B are schematic views of a deposition head 66 including a discharge plate 95 (95a and 95b). FIG. 13A is a schematic view of the deposition head 66 including the discharge plate 95a having a slit 96, and FIG. 13B is a schematic view of the deposition head 66 including the discharge plate 95b having discharge holes 97. An opening width of the slit 96 may be, for example, about 1 mm. In order to uniformly discharge the material gas from the deposition head 66, it is desirable that a multiple number of discharge holes 97 may be provided. An arrangement or the number of the discharge holes 97 may be determined in a way that allows the material gas to be uniformly discharged. Since the discharge plate 95 (95a and 95b) depicted in FIGS. 13A and 13B is provided in the opening 72 (73) of the deposition head 66, it may be possible to more uniformly discharge the material gas to the substrate G, so that a thin film of high uniformity can be formed. However, in the discharge plate 95a having the slit 96, there is a concern that the width of the slit 96 may be changed due to heat generated by temperature increase, and a distribution of the material gas may not be uniformized. Particularly, when a material gas of high temperature is used, it may be desirable to use the discharge plate 95b having the discharge holes 97. By way of example, a diameter of the discharge hole 97 may have a range of from about 1.5 mm to about 3.5 mm, and a pitch between the discharge holes 97 may be about 5 mm. Further, the discharge holes 97 are not limited to be arranged in a single line depicted in FIG. 13B, and can be arranged in two or more lines.

In the above-described embodiment, as depicted in FIG. 6, it has been described that heaters such as the sheath heater and the cartridge heater serving as the heaters 77 and 78 may be put in the groove 80 formed in the outer surface of the first casing 70. In its modification example (another embodiment), as depicted in FIG. 10, it has been described that the heater 77 may be provided in the space between the first casing 70 and the second casing 71 with the plate member 90 therebetween. However, a heater provided in the deposition head 66 is not limited to the above configuration. By way of example, a sealed space 100 may be formed between the first casing 70 and the second casing 71. A volatile liquid L and the pipe-shaped heater 77 whose temperature can be controlled may be provided in the sealed space 100.

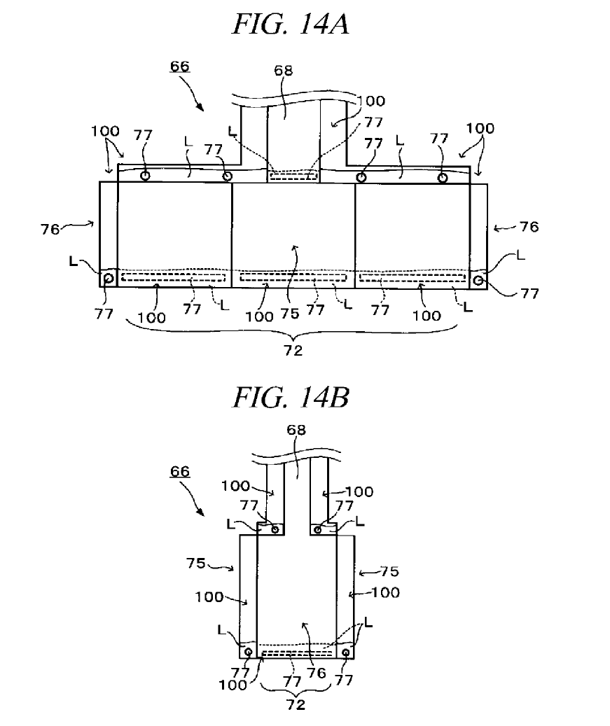

Hereinafter, as a third another embodiment of the present disclosure, there will be explained a deposition head 66 having the sealed space 100, with reference to the accompanying drawings. FIGS. 14A and 14B provide a schematic front view (FIG. 14A) and a schematic side view (FIG. 14B) of a deposition head 66 having the sealed space 100. In order to explain the inside of the sealed space 100, a cross section of a part of the sealed space 100 is illustrated. In the sealed space 100, the heater 77 and the liquid L may be sealed. The liquid L may include, for example, water or naphthalene, which can be evaporated at a certain temperature. The heater 77 may include, for example, a cartridge heater and a sheath heater.

As depicted in FIGS. 14A and 14B, the sealed space 100 may be formed in the entire surface (both side surfaces and 76 of the above-described embodiments) of a deposition head 66 except the opening 72 (lower surface of the deposition head 66 in FIGS. 14A and 14B). As depicted in FIGS. 14A and 14B, on the side surface 75 (larger than the side surface 76), three sealed spaces 100 may be formed so as to respectively correspond to three divided portions of the side surface 75 in a longitudinal direction. On the side surface 76, a single sealed space 100 may be formed so as to cover the entire surface thereof. Further, the sealed space 100 may be formed so as to cover the outer surface of the material supply line 68 configured to supply the material gas.

The inside of the sealed space 100 may be in a sealed state, and the liquid L and the heater 77 may be provided therein. The amount of the liquid L may not be sufficient enough to fill the entire inside of the sealed space 100, but may be sufficient to exist at a bottom portion of the sealed space 100. In the present embodiment, the heater 77 may be immersed in the liquid L existing within the sealed space 100. Further, the heater 77 may have a sufficient size/length to heat the liquid L existing at a bottom portion of the sealed space 100. The size/length thereof can be determined appropriately.

In the sealed space 100, the liquid L existing within the sealed space 100 may be evaporated by being heated by the heater 77. Evaporated steam may contact with the entire inner surface of the sealed space 100, so that the sealed space 100 can be heated over all. That is, the sealed space 100 may have a configuration/operation similar to a so-called “heat pipe”. In this case, the liquid L's steam may be cooled by means of heat exchange with the inner surface after contacting with the inner surface of the sealed space 100, and liquefied (liquid L) so as to exist within the sealed space 100. That is, the liquid L may circulate within the sealed space 100 while repeating evaporation and liquefaction. Further, in the present embodiment, a shape of the inner surface of the sealed space 100 is not limited, and may be a typical plane. However, in order to reflux the liquefied liquid L upon contacting with the inner surface of the sealed space 100, into the liquid L existing at the bottom portion of the sealed space 100 with more efficiency, desirably, the inner surface of the sealed space 100 may have a large surface area and a shape which may easily cause a capillary phenomenon. By way of example, the surface process may be performed on the inner surface of the sealed space 100 to have a mesh shape or a groove shape.

In the above-described deposition head 66 around which the sealed space 100 is formed, when a material gas is supplied, the liquid L within the sealed space 100 may be heated by the heater 77 so as to be vaporized. Therefore, the sealed space 100 may be filled with the vapor having an approximately constant temperature. Thus, the deposition head 66's side surface entirely covered by the sealed spaces 100 may be uniformly heated by the respective sealed spaces at a certain temperature. Therefore, the material gas supplied from the material supply line 68 may be uniformly heated within the deposition head 66 at a certain temperature. Since the sealed spaces 100 are provided in the entire side surface of the deposition head 66, the side surface can be uniformly heated with high accuracy. Further, the material gas within the deposition head 66 can be uniformly heated by radiant heat with high accuracy from the uniformly thermalized side surfaces of the deposition head 66.

Since a temperature of the heater 77 provided in each sealed space 100 can be controlled, an internal temperature of each sealed space 100 can be controlled. The internal temperature of each sealed space 100 can be controlled appropriately based on a measured temperature distribution within the deposition head 66, and the deposition head 66 can be uniformly heated to become a certain temperature with high accuracy. That is, even if a part of the deposition head 66 may have a temperature lower than other portions thereof, by appropriately controlling a temperature of each sealed space 100 corresponding to the low-temperature portion, the whole inside of the deposition head 66 can be quickly and uniformly heated.

It has been explained that in the present embodiment (third another embodiment), the side surface 75 of the deposition head 66 may be divided into three portions in a longitudinal direction, and the three sealed spaces 100 respectively corresponding thereto may be formed. The present disclosure is not limited to this embodiment. The number or positions of the sealed spaces 100 formed in the side surface of the deposition head 66 can be appropriately changed so as to efficiently and uniformly heat the inside of the deposition head 66.

In the above-described embodiment, the deposition head 66 may include the first casing 70 and the second casing 71. The deposition head 66 of the present disclosure is not limited thereto. In the present disclosure, the deposition head 66 need not have a casing. By way of example, a plate-shaped member in a casing shape may be provided.

In the above-described embodiment, the multiple protrusions 85 serving as the spacer members configured to bring the inner surface of the first casing 70 into partial contact with the outer surface of the second casing 71 may be formed in the entire outer surface of the second casing 71. However, the present disclosure is not limited thereto. The protrusions 85 may be formed on the inner surface of the first casing 70, or the protrusions 85 may be formed on the inner surface of the first casing 70 and the outer surface of the second casing 71. Here, the material of the protrusions 85 formed on the inner surface of the first casing 70 is different from that on the outer surface of the second casing 71. Further, as the spacer member, a filling material such as steel wool may be used.

### EXPERIMENTAL EXAMPLE

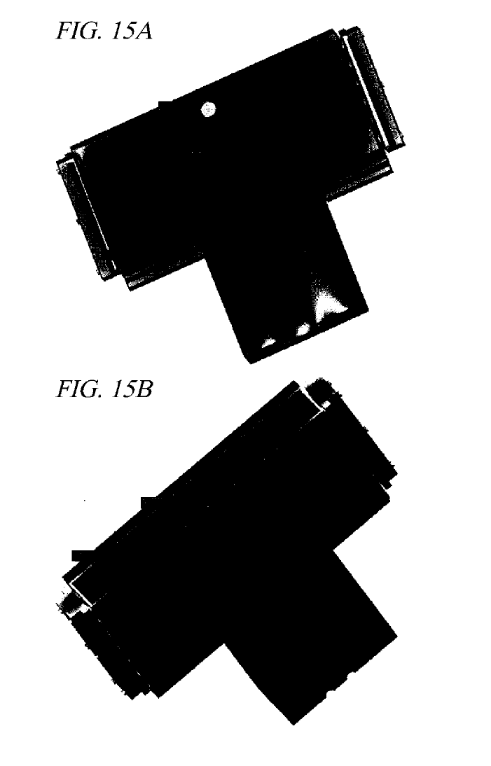

As an experimental example 1 of the present disclosure, a deposition head having a configuration depicted in FIG. 6 is actually provided in a deposition apparatus. An outer casing is made of copper; an inner casing is made of stainless steel; and an emboss processing is uniformly performed on the inner casing. Further, a pipe-shaped heater is actually provided at each position depicted in FIG. 6. Then, the deposition head is heated by each heater and a material gas is discharged from an opening. At this time, a surface temperature of the deposition head and temperature around the opening are analyzed (simulated). FIGS. 15Aa and 15B show a result of the analysis. To be specific, FIG. 15A shows the surface temperature of the deposition head, and FIG. 15B shows a result of the temperatures measured around the opening of the deposition head.

A temperature difference between a central portion of an outer wall and a periphery portion of the outer wall in FIG. 15A, and a temperature difference between the center portion of the opening and an end portion of the opening in FIG. 15B are about 1° C. or less, respectively. As a result, it can be assumed that the surface temperature of the deposition head and the temperatures around the opening of the deposition head have an equi-thermal property secured with high accuracy.

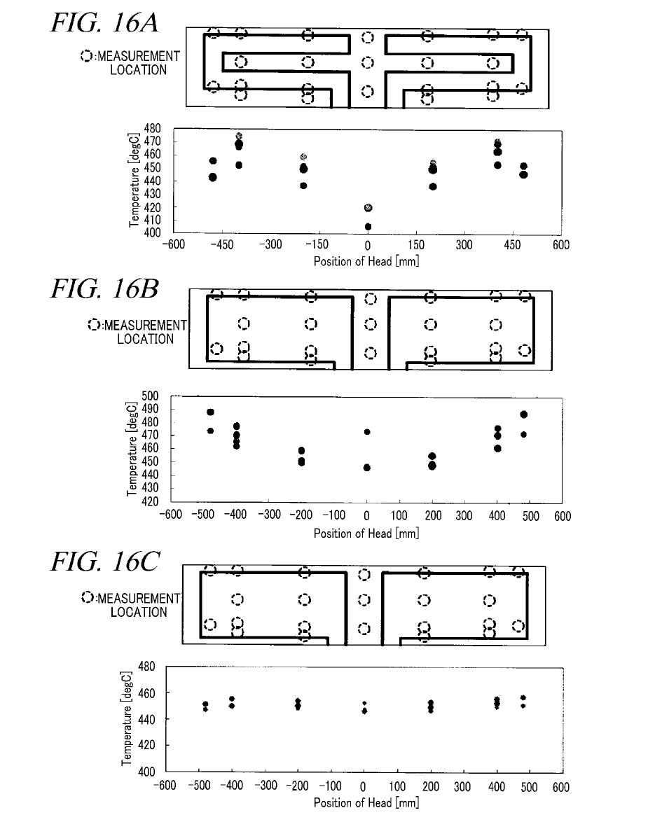

As an experimental example 2 of the present disclosure, there is measured a temperature distribution on a cross section within a deposition head while varying an arrangement of a heater and changing presence/absence of a copper coating as a thermal conductive film. FIGS. 16A to 16C are graphs showing measurement positions and temperature distributions in this deposition head. FIGS. 15A and 15B show measurement data with a longitudinal axis thereof denoting a temperature (° C.) and a horizontal axis thereof denoting a distance (mm) from the center of the deposition head in a width direction. However, all the measurements shown in FIGS. 16A to 16C are carried out for a deposition head in which a heater is provided in an outer surface of an inner casing.

FIG. 16A is a graph showing a result of a temperature difference measured on a cross section within a deposition head when a heater density is high as depicted in FIG. 11A. Meanwhile, FIG. 16B is a graph showing a result of a temperature difference measured on a cross section within a deposition head when a heater density is low as depicted in FIG. 11B. FIG. 16C is a graph showing a result of a temperature difference measured on a cross section within a deposition head in which an outer surface of an inner casing is covered with a copper coating when a heater density is low as depicted in FIG. 11B.

As depicted in FIG. 16A, when the heater density is high, the temperature difference on the cross section within the deposition head may be about ±35° C. at most with respect to a desired internal temperature of about 450° C. Further, as depicted in FIG. 16B, when the heater density is low, the temperature difference on the cross section within the deposition head may be about ±20° C. at most with respect to a desired internal temperature of about 450° C. Meanwhile, as depicted in FIG. 16C, if a surface having a heater is covered with the copper coating when the heater density is low, the temperature difference on the cross section within the deposition head may be about ±4.5° C. at most with respect to a desired internal temperature of about 450° C.

It can be seen from the result of the experimental example 2 that when the heater density is suppressed to be low and the surface having the heater is covered with the cooper coating (thermal conductive film), the temperature difference on the cross section within the deposition head can be reduced and a sufficient equi-thermal property can be secured. That is, by forming the thermal conductive film on the surface having the heater, the number of heaters can be reduced and the equi-thermal property can be secured, resulting in a cost reduction.

### INDUSTRIAL APPLICABILITY

The present disclosure can be applied to, for example, a deposition head used for depositing an organic film in manufacturing an organic EL device and a deposition apparatus including the deposition head.

What is claimed is:

1. A deposition head provided within a deposition apparatus for forming a thin film on a substrate and configured to discharge a material gas toward the substrate, the deposition head comprising:
an outer casing; and
an inner casing provided within the outer casing and into which the material gas is introduced,
wherein in the inner casing, an opening configured to discharge the material gas toward the substrate is formed, and
a heater configured to heat the material gas is provided at an outer surface of the outer casing or in a space between the outer casing and the inner casing.

2. The deposition head of claim 1,
wherein the heater is fixed to a plate member provided between the outer casing and the inner casing.

3. The deposition head of claim 1,
wherein the heater is provided along a periphery of a side surface of the outer casing or the inner casing.

4. The deposition head of claim 1,
wherein the heater includes a sheath heater or a cartridge heater.

5. The deposition head of claim 1,
wherein a spacer member configured to bring an inner surface of the outer casing into partial contact with an outer surface of the inner casing is provided on at least one of the outer casing and the inner casing.

6. The deposition head of claim 1,
wherein a sealed space is formed between the outer casing and the inner casing,
the heater is provided within the sealed space, and
a volatile liquid is provided in the sealed space.

7. The deposition head of claim 1,
wherein thermal conductivity of the outer casing is equal to or higher than thermal conductivity of the inner casing.

8. The deposition head of claim 5,
wherein the spacer member is provided on either or both of the outer casing and the inner casing, and a spacer member provided on the outer casing is made of a material different from a material of a spacer member provided on the inner casing.

9. The deposition head of claim 5,
wherein the spacer member includes a plurality of protrusions formed by press molding or a filling material.

10. The deposition head of claim 9,
wherein the press molding includes an emboss processing or a welding processing.

11. The deposition head of claim 1,
wherein a material of the outer casing includes stainless steel or copper.

12. The deposition head of claim 1,
wherein a material of the inner casing includes stainless steel.

13. The deposition head of claim 1,
wherein a thickness of at least a part of the inner casing is about 3 mm or less.

14. The deposition head of claim 1,
wherein a gas dispersion plate is provided within the inner casing.

15. The deposition head of claim 14,
wherein the gas dispersion plate includes a mesh-shaped baffle plate or a punching metal plate.

16. The deposition head of claim 1,
wherein a thermal conductive film is formed on either or both of the inner casing and the outer casing.

17. The deposition head of claim 16,
wherein the thermal conductive film is formed on at least an outer surface of the inner casing.

18. The deposition head of claim 1,
wherein a discharge plate configured to uniformly discharge the material gas is provided in the opening.

19. The deposition head of claim 18,
wherein the discharge plate includes a slit configured to discharge the material gas.

20. The deposition head of claim 18,
wherein the discharge plate includes multiple discharge holes configured to discharge the material gas.

21. The deposition head of claim 18,
wherein the discharge plate is formed of a stainless steel plate, a stainless block, a cooper plate, or a copper block.

22. A deposition apparatus for forming an organic thin film on a substrate, the deposition apparatus comprising:
a processing chamber configured to accommodate therein a substrate; and
a deposition head, as claimed in claim 1, that includes an opening configured to discharge a material gas toward the substrate within the processing chamber.

23. The deposition apparatus of claim 22, further comprising:
a carrier gas supply unit configured to supply a carrier gas that transports the material gas.

24. The deposition apparatus of claim 22,
wherein an inside of the processing chamber is depressurized.
